(19) United States
(12) Patent Application Publication
(10) Pub. No.: US 2005/0048761 A1
(43) Pub. Date: Mar. 3, 2005

(54) Conducting wire and contact opening forming method for reducing photoresist thickness and via resistance

(75) Inventors: Chih-Ching Lin, Taoyuan City (TW); Yi-Nan Chen, Taipei (TW)

Correspondence Address: BACON & THOMAS, PLLC, 625 SLATERS LANE, FOURTH FLOOR, ALEXANDRIA, VA, 22314, US

(73) Assignee: NANYA Technology Coroporation, Taoyuan (TW)

(21) Appl. No.: 10/646,896

(22) Filed: Aug. 25, 2003

(51) Int. Cl. H01L 21/4763; H01L 21/44

(52) U.S. Cl. 438/622; 438/643; 438/688

(57) ABSTRACT

Disclosed is a method for forming conducting wire and contact opening in a semiconductor device. The method comprises steps of providing a substrate; forming a first dielectric layer on the substrate; digging a via in the first dielectric layer and filling metal therein; forming a conductor layer on the first dielectric including the via; forming a metal layer on the conductor layer; removing unnecessary portions of the conductor/metal layers to define recesses, with the left portions to form conducting wires; applying a second dielectric layer to fill the recesses and performing planarization thereto to expose the conducting wires; forming a third dielectric layer; forming photoresist of predetermined pattern on the third dielectric layer; removing predetermined portion of the third dielectric layer to form a contact opening; and removing the photoresist.

### BACKGROUND OF THE INVENTION

1. Field of the Invention

This invention relates to a process for manufacturing conducting wires and contact windows in a semiconductor structure, and more specifically, to a method for reducing photoresist thickness and via resistance in the manufacturing process for conducting wires.

2. Description of the Prior Art

The process for manufacturing conducting wires is an important stage in the manufacture for semiconductor device such as DRAM.

The process for manufacturing conducting wires of prior art will be described with reference to FIG. 1.

First of all, a first dielectric layer 12 is formed on a semiconductor substrate 10, and the first dielectric layer 12 is dug to form a via 14, and then the via 14 is filled with metal. The constructed structure is shown in FIG. 1a.

Subsequently, a metal layer 16 is formed on the first dielectric layer 14 including the via 14 filled with metal. The material of the metal layer 16 can be aluminum or any other suitable material. In practical process, thin Ti/TiN barrier layers 162 and 164 are respectively formed on the bottom and top of the metal layer 16, as shown in FIG. 1b.

Then, as shown in FIG. 1c, photoresist portions 182, 184, 186 are formed on the structure of FIG. 1b in order to remove unnecessary portions of the metal layer 16/barrier layers 162, 164, so that recesses 15 are defined, and accordingly conducting wires are formed, as shown in FIG. 1d.

However, in the step of forming the photoresist, the applied photoresist must have sufficient thickness, so that the aspect ratios of some photoresist portions are large. If the aspect ratio of the photoresist portion exceeds a certain degree, it is likely that a slant or even collapse phenomenon will happen, as indicated by the reference number 186′ in FIG. 1c′. Under the circumstance that the photoresist portion slants or collapses, the accuracy of the etching profile is influenced, causing the profile of the left metal portion after etching differs from the predetermined pattern.

In the subsequent process for producing a contact opening, a second dielectric layer 152 is formed to fill in the recesses 15, and is planarized. Then a third dielectric layer 17 is formed on the entire structure, as shown in FIG. 1e.

Then, photoresist portions 19 are formed on the third dielectric layer 17, as shown in FIG. 1f.

Finally, a contact opening 175 is opened by etching process, the photoresists are removed, as shown in FIG. 1g. However, in the etching process, the portion of the barrier layer 164 of the conducting wire corresponding to the contact opening is usually etched off at the same time, causing the damage of the conducting wire, and therefore the via resistance is increased and hardly controlled.

### SUMMARY OF THE INVENTION

An objective of the present invention is to provide a method for forming conducting wire and contact opening in semiconductor structure, which is able to reduce the thickness of the photoresist used in the process.

Another objective of the present invention is to provide a method for forming conducting wire and contact opening in semiconductor structure, by which the via resistance can be well controlled.

According to an aspect of the present invention, in the method for forming conducting wire and contact opening in semiconductor structure, an additional metal layer is formed on the metal portion constituting the conducting wire before forming photoresist to etch the conducting wire.

According to another aspect of the present invention, in the method for forming conducting wire and contact opening in semiconductor structure, the material of the formed additional metal layer is different from that of the metal portion constituting the conducting wire.

According to a further aspect of the present invention, in the method for forming conducting wire and contact opening in semiconductor structure, the material of the formed additional metal layer is tungsten.

### BRIEF DESCRIPTION OF THE DRAWINGS

The following drawings are only for illustrating the mutual relationships between the respective portions and are not drawn according to practical dimensions and ratios. In addition, the like reference numbers indicate the similar elements.

FIGS. 1a to 1c, 1c and 1d to 1g are sectional schematic diagrams showing the respective steps of the conducting wire and contact opening forming process of the prior art; and

FIGS. 2a to 2h are sectional schematic diagrams showing the respective steps of the conducting wire and contact opening forming method in accordance with the present invention.

### DETIALED DESCRIPTION OF THE PREFERRED EMBODIMENT

The technical contents, objectives and effects achievable disclosed by the present invention will be described in detail as follows.

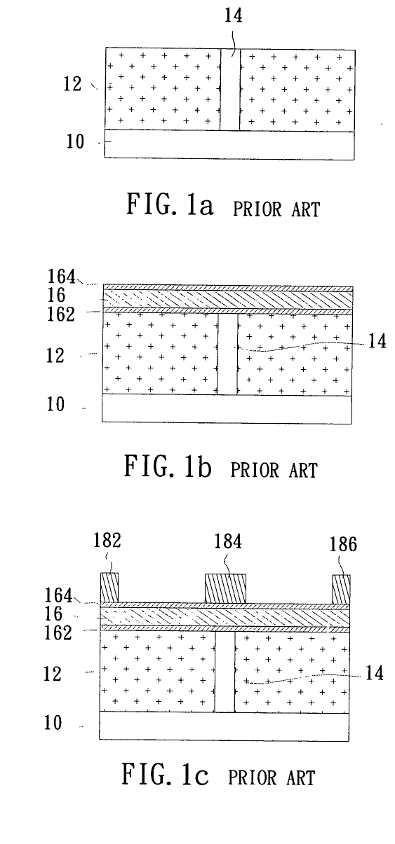

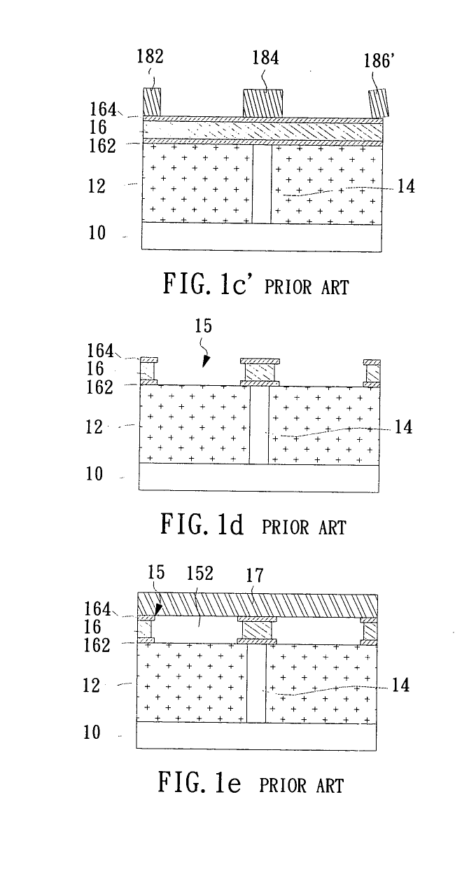

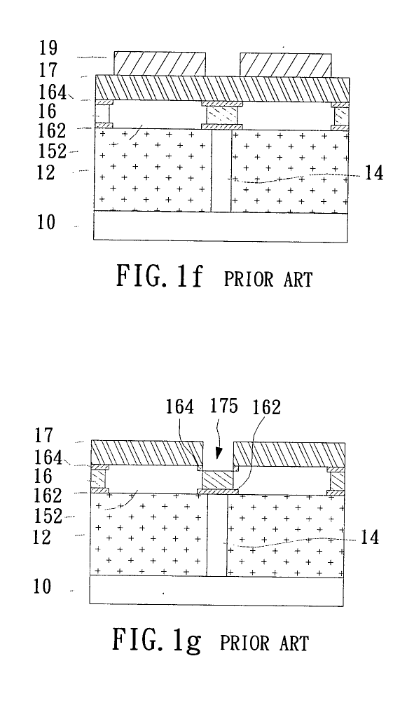

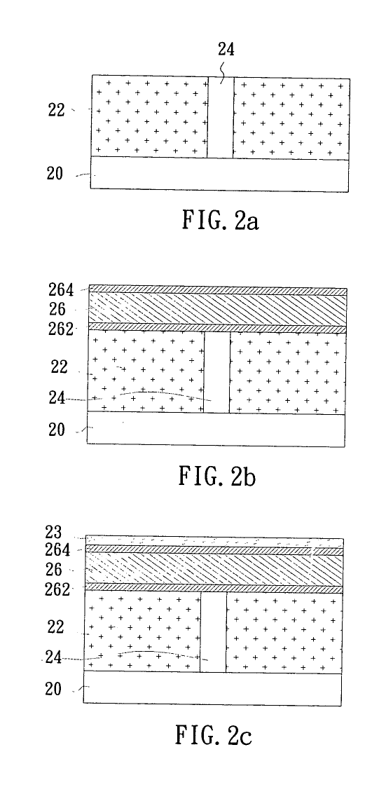

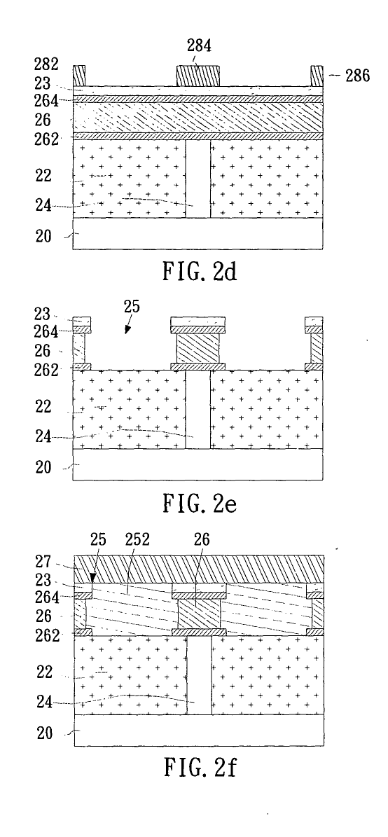

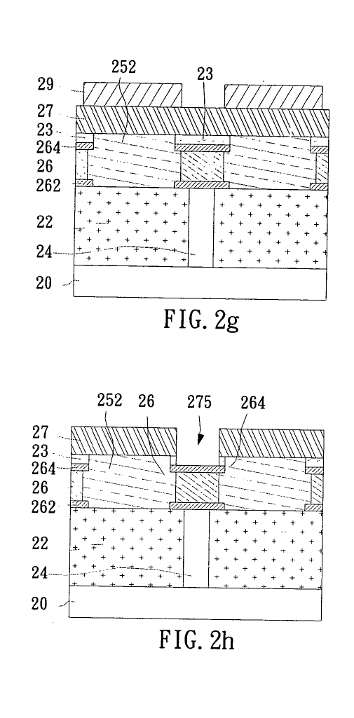

The structure shown in FIGS. 2a and 2b is the same as that shown in FIGS. 1a and 1b, and therefore the descriptions thereabout are omitted. In these drawings, reference number 20 indicates a substrate, 22 is a first dielectric layer, 24 is a via filled with metal, 26 is a first metal layer, which can be of aluminum and has barrier layers 262 and 264 formed on the top and bottom surfaces thereof. The material of the barrier layer 262 and 264 can be Ti/TiN. The combination of the first metal layer and the barrier layers refers to a conductor layer.

As shown in FIG. 2c, in the structure of FIG. 2b, a second metal layer 23 is formed on the conductor layer. The material of the second metal layer 23 can be tungsten or any other proper material.

As shown in FIG. 2d, photoresist of a predetermined pattern is formed on the second metal layer 23 as photoresist portions 282, 284, 286. As shown in this drawing, the second metal layer 23 has a certain thickness, and thus, the thickness of the applied photoresist does not need to be so thick as the prior art. Accordingly, the photoresist portion such as that indicated by reference number 286 has an aspect ratio smaller than that of the prior art, and therefore the slant or even collapse phenomenon will not occur.

Subsequently, the unnecessary portions of the metal layers 23, 26 and barrier layers 262, 264 are removed to form recesses 25, thereby forming conducting wires. Finally, the photoresist is removed, as shown in FIG. 2e.

In the subsequent process for forming the contact opening, a second dielectric layer 252 is formed to fill in the recesses 25, and is planarized to expose the conducting wires. Then a third dielectric layer 27 is formed on the entire structure, as shown in FIG. 2f.

Photoresist of a predetermined pattern is formed on the third dielectric layer 27 as photoresis portions 29, as shown in FIG. 2g.

Finally, a predetermined portion of the dielectric layer 27 is removed by etching to open a contact opening 275, and then the photoresist is removed, as shown in FIG. 2h. As can be seen from this drawing, upon opening the contact opening 275, the etching is stopped at the barrier layer 264 because of the function of the second metal layer 23. Therefore, the integrity of the conducting wire can be maintained, and accordingly the via resistance can be well controlled and reduced.

While the embodiment of the present invention is illustrated and described, various modifications and alterations can be made by persons skilled in this art. The embodiment of the present invention is therefore described in an illustrative but not restrictive sense. It is intended that the present invention may not be limited to the particular forms as illustrated, and that all modifications and alterations which maintain the spirit and realm of the present invention are within the scope as defined in the appended claims.

1. A method for forming conducting wires in a semiconductor device, comprising steps of:
providing a substrate;
forming a first dielectric layer on said substrate;
digging a via in said first dielectric layer and filling said via with metal;
forming a conductor layer on said first dielectric layer including said via;
forming a metal layer on said conductor layer;
forming photoresist of a predetermined pattern on said metal layer;
removing portions of said conductor layer and metal layer not covered with said photoresist to form the conducting wire; and
removing said photoresist.

2. The method as recited in claim 1, wherein the material of said metal layer is different from that of the conductor layer.

3. The method as recited in claim 2, wherein the material of said metal layer is tungsten.

4. The method as recited in claim 1, wherein said conductor layer has an another metal layer and barrier layers formed on the top and bottom surfaces of said another metal layer.

5. The method as recited in claim 4, wherein the material of said another metal layer of the conductor layer is aluminum.

6. The method as recited in claim 4, wherein the material of the barrier layers is Ti/TiN.

7. A method for forming conducting wires and contact openings in a semiconductor device, comprising steps of:
providing a substrate;
forming a first dielectric layer on said substrate;
digging a via in said first dielectric layer and filling said via with metal;
forming a conductor layer on said first dielectric layer including said via;
forming a metal layer on said conductor layer;
forming photoresist of a predetermined pattern on said metal layer;
removing portions of said conductor layer and said metal layer not covered with the photoresist to form recesses, leaving the remained portion as the conducting wire;
removing said photoresist;
coating a second dielectric layer to fill said recesses and performing planarization to expose said conducting wire;
forming a third dielectric layer on said second dielectric layer and said conducting wire;
forming photoresist of a predetermined pattern on said third dielectric layer;
removing portions of said third dielectric not covered with the photoresist to form the contact opening; and
removing the photoresist.

8. The method as recited in claim 7, wherein the material of said metal layer is different from that of the conductor layer.

9. The method as recited in claim 8, wherein the material of said metal layer is tungsten.

10. The method as recited in claim 7, wherein said conductor layer has an another metal layer and barrier layers formed on the top and bottom surfaces of said another metal layer.

11. The method as recited in claim 10, wherein the material of said another metal layer of the conductor layer is aluminum.

12. The method as recited in claim 10, wherein the material of the barrier layers is Ti/TiN.
